(19) United States
(12) Patent Application Publication
(10) Pub. No.: US 2025/0006780 A1
(43) Pub. Date: Jan. 2, 2025

(54) EXTREMELY HIGH DENSITY SILICON CAPACITOR

(71) Applicant: INTERNATIONAL BUSINESS MACHINES CORPORATION, ARMONK, NY (US)

(72) Inventors: Joshua M. Rubin, Albany, NY (US); Alexander Reznicek, Troy, NY (US); Theodorus E. Standaert, Clifton Park, NY (US); Koichi Motoyama, Clifton Park, NY (US)

(21) Appl. No.: 18/346,125

(22) Filed: Jun. 30, 2023

(51) Int. Cl. H01L 21/02; H01G 4/012; H01G 4/33; H01G 4/008

(52) U.S. Cl. CPC H01L 28/87; H01G 4/012; H01G 4/33; H01L 28/91; H01G 4/008

(57) ABSTRACT

A pillar or trench structure in a substrate includes vertical portions and one or more indented cavities in a sidewall between the vertical portions. The indented cavities are partial undercuts substantially traverse to the vertical portions pillar structure, or separate undercuts attached to an anchor. A higher capacitance density is achieved through the layering of multiple conductive contact layers and insulating layers in the undercuts and the vertical portions of the pillar or trench structure.

### BACKGROUND

### Technical Field

The present disclosure generally relates to capacitor structures, and more particularly, to silicon capacitors having extremely high density.

### Description of the Related Art

As increasingly dense circuitry continues to be developed, capacitor research and development to provide higher densities for capacitors is also underway. There continues to be a growing demand for more capacitors with higher density.

### SUMMARY

According to one embodiment, a pillar or trench structure in a substrate includes vertical portions and one or more indented cavities in a sidewall between the vertical portions. The indented cavities are partial undercuts substantially traverse to the vertical portions pillar structure, or separate undercuts attached to an anchor. A higher capacitance density is achieved through the layering of multiple conductive contact layers and insulating layers in the undercuts and the vertical portions of the pillar or trench structure.

### BRIEF DESCRIPTION OF THE DRAWINGS

The drawings are of illustrative embodiments. They do not illustrate all embodiments. Other embodiments may be used in addition to or instead of those shown. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 is an illustration of a high-density capacitor according to an illustrative embodiment.

FIGS. 2A, 2B, 2C, and 2D illustrate a wrap-around metal-insulator-metal (MIM) capacitor with a silicon substrate and undercut according to an illustrative embodiment.

FIGS. 3A, 3B, 3C, 3D and 3E illustrate a wrap-around metal-insulator-metal (MIM) capacitor with an insulating core according to an illustrative embodiment.

FIGS. 4A, 4B, 4C, 4D and 4E illustrate a wrap-around metal-insulator-metal (MIM) capacitor with a conducting core plate according to an illustrative embodiment.

FIGS. 5A and 5B illustrate capacitors with density differences based on etching according to an illustrative embodiment.

FIG. 5C is a 3D example of a density difference of the capacitor structure based on etching according to an illustrative embodiment.

FIG. 6 is a flowchart of a method of fabricating a high-density capacitor according to an illustrative embodiment.

FIG. 7 is an illustration of the fabrication operations according to an illustrative embodiment.

### DETAILED DESCRIPTION

In the following detailed description, numerous specific details are set forth by way of examples to provide a thorough understanding of the relevant teachings. However, it is to be understood that the present teachings may be practiced without such details. In other instances, well-known methods, procedures, components, and/or circuitry have been described at a relatively high-level, without detail, to avoid unnecessarily obscuring aspects of the present teachings. It is also to be understood that the present disclosure is not limited to the depictions in the drawings, as there may be fewer elements or more elements than shown and described.

In discussing the present technology, it may be helpful to describe various salient terms. In one aspect, spatially related terminology such as “front,” “back,” “top,” “bottom,” “beneath,” “below,” “lower,” above,” “upper,” “side,” “left,” “right,” and the like, is used with reference to the direction of the Figures being described. Since components of embodiments of the disclosure can be positioned in a number of different directions, the directional terminology is used for purposes of illustration and is in no way limiting. Thus, it will be understood that the spatially relative terminology is intended to encompass different directions of the device in use or operation in addition to the direction depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other directions) and the spatially relative descriptors used herein should be interpreted accordingly.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

As used herein, the term “pillar structure” may be any desired shape, e.g., cylindrical, square, etc. Trenches may be made in the substrate instead of pillar structures. When trenches are used, a network of connected anchors can be achieved. For instance, one could have a honeycomb structure, where the trenches are formed in a regular array with silicon surrounding them. There can be a partial or a full undercut in such a structure with trenches.

### Technical Advantages and Support

It is to be understood that some of the advantages of the present disclosure are provided herein below. However, a person of ordinary skill in the art will appreciate that additional advantages may exist in addition to those described herein.

In an embodiment, a capacitor structure, includes a substrate, a pillar structure within the substrate having vertical portions etched in the substrate, one or more indented cavities isotropically etched and extending from between the vertical portions of the pillar structure substantially transverse to the vertical portions of the pillar structure, and at least two conductive contact layers arranged within the vertical portions and the indented cavities of the pillar structure. The at least two conductive contact layers extend to an exterior of the substrate. A high-k dielectric material is arranged between the at least two conductive contact layers to insulate the at least two conductive contacts from each other. A more dense capacitor than known heretofore is created with the pillar structure having indented cavities. Further, the two vertical portions overcome technical challenges to provide an additionally denser structure.

In an embodiment, which may be combined with the preceding embodiment, the vertical portions of the pillar structure are anisotropically etched. The anisotropically etching permits a desired direction.

In an embodiment, which may be combined with one or more of the preceding embodiments, the three conductive contact layers and two high-k dielectric layers are alternately arranged within the vertical portions and the indented cavities of the pillar structure. The three conductive contact layers and the two high-k dielectric layers extend from the pillar structure to a top surface of the substrate. A higher density capacitor is achieved with three or more conductive layers alternately arranged with dielectric material layers.

In an embodiment, which may be combined with one or more of the preceding embodiments, the substrate is a silicon substrate. The Si substrate provides for a more efficient capacitor structure.

In an embodiment, which may be combined with one or more of the preceding embodiments, the substrate is a silicon-germanium (SiGe) substrate. Si—Ge is used for improved efficiency.

In an embodiment, which may be combined with one or more of the preceding embodiments, the three conductive contact layers are metal layers forming capacitor plates that are alternately arranged with the high-k dielectric layers. Having three conductive contact layers in the capacitor structure provides for a denser capacitor structure. Cobalt, Rh, Ta, TaN, AlCu, or any other suitable metal may be used for the conductive contact layers.

In an embodiment, which may be combined with one or more of the preceding embodiments, the metal layers include a top contact, a middle contact, and a bottom contact alternately arranged with the high-k electric layers. The three contacts provide for more flexibility and for varied amounts of capacitance.

In an embodiment, which may be combined with one or more of the preceding embodiments, the bottom contact is a doped Si (or semiconductor) material. The doped Si material allows for improved density of the capacitor structure.

In an embodiment, which may be combined with one or more of the preceding embodiments, the indented cavities include a plurality of partial undercuts in the substrate substantially transverse to the vertical portions of the pillar structure. The undercuts increase the density of the capacitor.

In an embodiment, which may be combined with one or more of the preceding embodiments, the indented cavities include a plurality of full undercuts in the substrate substantially transverse to a direction of the pillar structure, and at least one anchor attached to the full undercuts. Full undercuts can create denser capacitance.

In an embodiment, which may be combined with one or more of the preceding embodiments, the indented cavities are arranged in a sidewall of the pillar structure. The indented cavities increase the density of the capacitor.

In an embodiment, which may be combined with one or more of the preceding embodiments, the pillar structure is a plurality of pillars laterally arranged in the substrate. Additional pillars provide for an integrated structure with increased capacitance.

In an embodiment, which may be combined with one or more of the preceding embodiments, the pillar structure is arranged in a trench within the substrate. This arrangement makes for a more durable structure.

In an embodiment, a capacitor structure includes a substrate, and a pillar structure within the substrate. One or more indented cavities extend from the pillar structure within the substrate. A plurality of alternately arranged conductive layers and high-k dielectric layers are arranged within the pillar structure and the indented cavities. The plurality of alternately arranged conductive layers and high-k dielectric layers extend from the pillar structure to a top surface of the substrate. Increased density is provided by this structure.

In an embodiment, which may be combined with the preceding embodiment, the capacitor structure is a discrete capacitor. Discrete capacitors are typically a cost-effective solution for providing a large quantity of capacitance near a circuit/device that draws current. Discrete capacitors can use processes that are not compatible with CMOS processing.

In an embodiment, which may be combined with one or more of the preceding embodiments, the capacitor structure is an integrated capacitor. An integrated capacitor saves on space and the structure is more efficient than known capacitors. The integrated capacitor is co-integrated with other devices, such as transistors, diodes, inductors, etc.

In an embodiment, a metal-insulator-metal (MIM) capacitor includes a substrate having alternating layers fully undercut, the fully undercut layers are a plurality of plates. An anchor is attached to the substrate and to the plurality of plates. A plurality of plates is attached to the anchor; wherein each plate includes a core, and at least two metal layers are separated by a high-k insulator on the core. At least two contacts are connected respectively to one of the two metal layers. This construction permits the undercuts formed under the layers without the complexity of a pillar structure (protective films used on the sides of a pillar structure during formation are avoided).

In an embodiment which may be combined with the preceding embodiment, each plate includes an insulating core, a first metal layer deposited on the insulating core, a high-k layer on the first metal layer, and a second metal layer deposited on the high-k layer. Each contact is connected to one of the first metal layer or the second metal layer. The plurality of plates is vertically arranged, and a bottom plate is in contact with the substrate. The use of an insulating core allows for a bottom plate of the plurality of plates to be in contact with the substrate, and insulated cores may be shorted together for less complex construction.

In an embodiment which may be combined with one or more of the preceding embodiments, one of the two metal layers of each plate includes a conductive core, a high-k layer on the conductive core, and a second metal layer deposited on the high-k layer; and each contact is connected to one of the first metal layer or the second metal layer. The undercuts in the layered structure on the substrate allows for higher density capacitors because of the undercuts.

### Overview

The present disclosure provides for a higher-density capacity capacitor than known heretofore. In an illustrative embodiment, a pillar structure has multiple vertical portions with indented cavities formed between the vertical portions. The pillar structure has conductive contact layers and a high-k density dielectric layer between the conductive contact layers. This pillar structure overcomes difficulties in constructing vertical portions directionally etched (e.g., anisotropic etching), with isotropic etched cavities between the vertical portions. A protective film is used along the sidewalls of the vertical portions to protect the vertical portions from the isotropic etching. The high-k dielectric, the conductive layers arranged in both the vertical portions of the pillar structure, and the indented cavities, increase the density of the capacitor structure.

In another illustrative embodiment, three conductive contact layers are arranged within the pillar structure and the indented cavities. This pillar structure may optionally have multiple vertical portions, or may be a single vertical portion with the indented cavity, for example, at a lower portion of the pillar. The three conductive contact layers are alternately arranged with two high-k dielectric layers. The three conductive contact layers form a top contact, a middle contact, and a bottom contact of the capacitor structure. The arrangement with the two high-k dielectric layers provides for a high-density capacitor structure.

### EXAMPLE EMBODIMENT

The capacitor of the present disclosure, may have one or more pillar structures within undercuts in a substrate. The substrate may be made of various of materials, such as doped or undoped silicon, glass, dielectrics, etc. For example, the substrate may include a semiconductor-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating films on top. There can basically be any combination of insulators, conductors, or semiconductors used to form the structure. These materials can be stacked in any suitable fashion to enable formation of the structure (undercuts and electrical connectivity). Therefore, one could even start off with a stack of metals and insulators on top of a silicon substrate, for instance.

Other materials that may be used for the substrate include, without limitation, sapphire, aluminum oxide, germanium, gallium arsenide (GaAs) or any of the other III-V periodic table compounds, indium phosphide (InP), silicon carbide (SiC), a superconducting alloy of silicon and germanium, quartz, etc. Thus, as used herein, the term substrate refers to a foundation upon which various high density capacitor structures can be built.

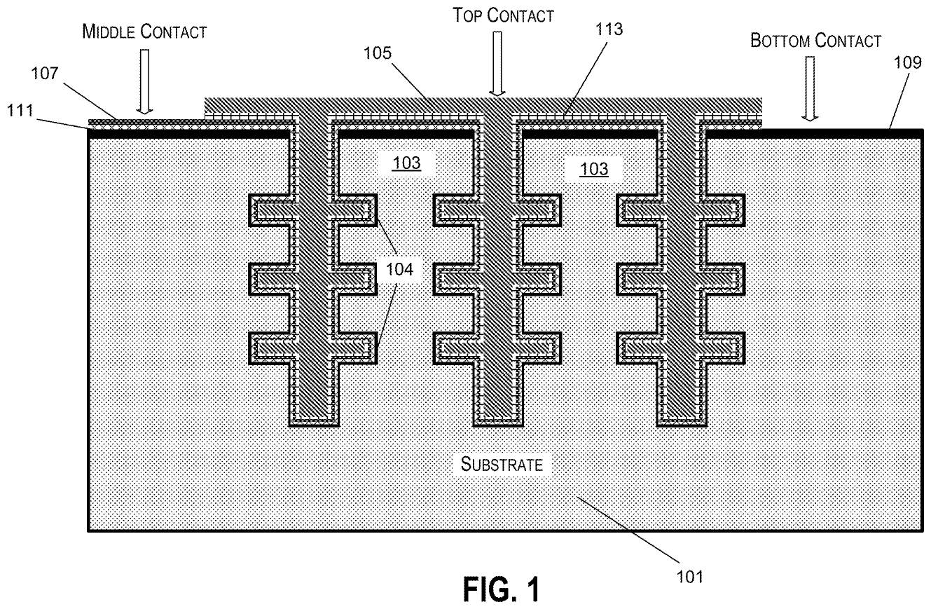

FIG. 1 is an illustration of a high-density capacitor according to an illustrative embodiment. The substrate 101 may be made of Silicon (Si), Si-Germanium (Si—Ge) or other types of known materials such as discussed in the above paragraph. The pillars 103 have indented cavities 104 that may be partial undercuts (as shown, or full undercuts). In this embodiment, three conductive contact layers 105, 107, and 109 are referred to as a top contact 105, middle contact 107, and bottom contact 109. The three conductive contact layers are alternately arranged with dielectric layers 111, 113. However, in an alternative embodiment, there may be two conductive contact layers and one high-k dielectric material.

In an alternative embodiment, the pillars may have one vertical portion, and the structure still has three conductive contacts 105, 107, 109 as shown in FIG. 1, with two dielectric layers 111, 113, as shown. It is to be appreciated that the density of the capacitor may be increased with an increased quantity of indented cavities as shown in FIG. 1.

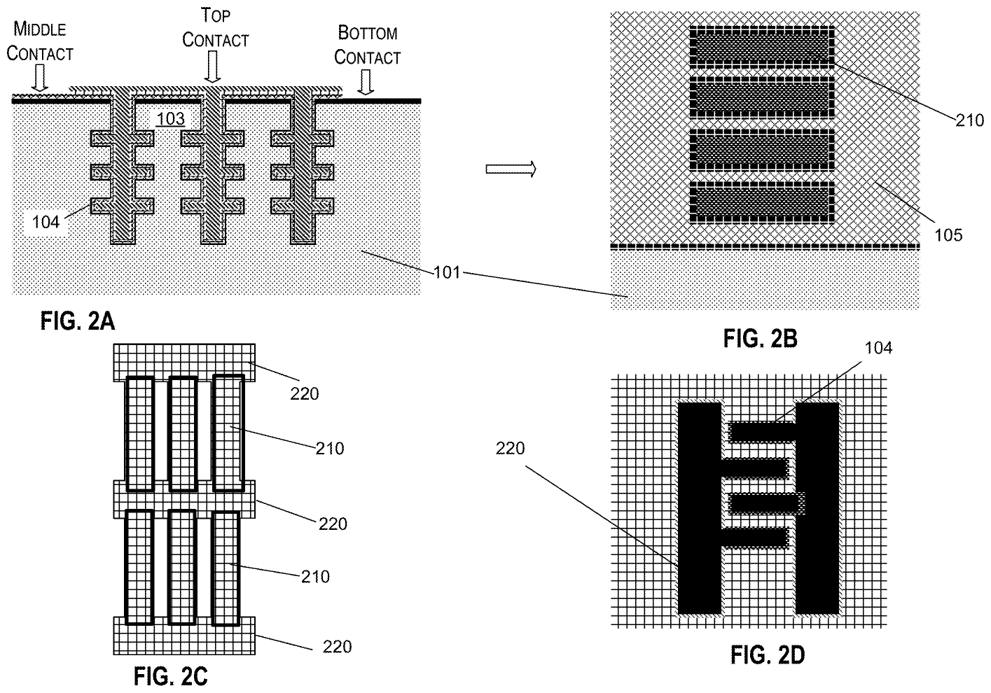

FIGS. 2A, 2B, 2C, and 2D are an illustration of a wrap-around metal-insulator-metal (MIM) capacitor with a silicon substrate and undercut according to an illustrative embodiment. FIG. 2A is an overview of a silicon substrate 101 from FIG. 1 in which two pillar structure 103 capacitors are shown with indented cavities 104. The indented cavities in FIG. 2A are partial undercuts. The pillars 103 can be constructed of various shapes and the partial undercuts of silicon in the indented cavities 104 do not require anchors because there is still an attachment to the pillar 103.

FIG. 2B shows a full undercut of silicon 210 (e.g., each having a high-k insulator 211). With the full undercuts, anchors 220 (such as shown in FIGS. 2B and 2C are used to hold the full undercuts 210 in place. Depending on the dimension, there can be a single anchor 220 in a cantilever arrangement, and interdigitate fingers, such as shown in FIG. 2D with the partial undercuts. FIG. 2C is a top-down view showing the full undercuts 210 attached to the anchors.

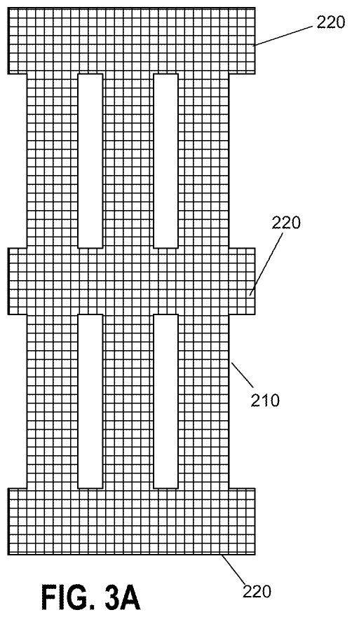

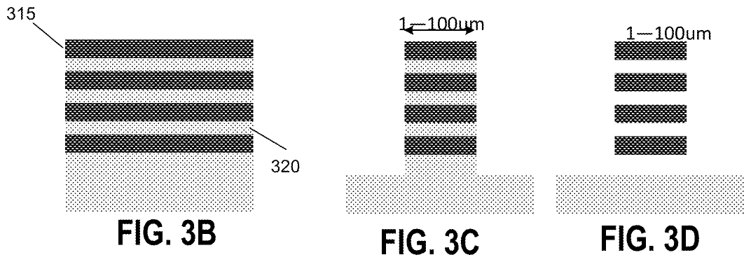

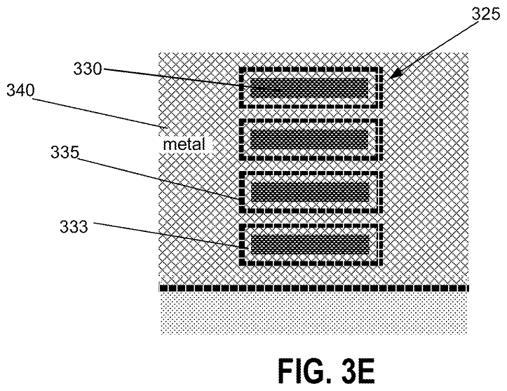

FIGS. 3A, 3B, 3C, 3D and 3E illustrate a wrap-around metal-insulator-metal (MIM) capacitor with an insulating core, according to an illustrative embodiment. In a top-down view in FIG. 3A, there is shown the anchors 220 and the contact region 210. The contact region 210 may be arranged over the anchors 220 because the films can extend there. The anchors 220 should be made to be larger than the undercuts. More specifically, if an undercut is x units, then the anchor will typically be more than 2× units wide. However, the specific dimensions depend on the geometry of the anchor.

With regard to the wrap around MIM capacitor with an insulating core, it should be noted the drawings structurally distinguish from epitaxial films used in a front end of line (FEOL) construction. FIG. 3B shows in cross section layers of SiO₂ 315 (alternatively the SiO₂ may be replaced by SiN) and layers of silicon 320. The SiO₂ 315 layers are about 1-5 μm in thickness, and the silicon layers 320 is about 100 to 500 nm. FIG. 3C shows the stack via a cutline shown in FIG. 3A, and FIG. 3D shows the stack after an etching of Tetramethylammonium hydroxide (TMAH) is used to remove the silicon. FIG. 3E shows four plates 325 on the substrate having an insulating core 330 that serves as a template. For example, each deposit plate 325 has an insulating core, a first metal layer 333 is deposited around the insulating core, followed by a high-k layer 335 on the first metal layer 333 and a second metal layer 340. Although four plates are shown, the disclosure is not limited to a specific quantity. For example, there can be three or more plates 325 which have contacts. An anchor (such as the anchor 220 shown in FIG. 3A is used to secure the deposit plates 325. A patterning of each plate 325 can be achieved in various ways. For instance, one may deposit a plate 325 on the substrate, pattern the plate, then deposit high-k, then deposit another plate, pattern the plate, and also pattern the previous high-k layer. Or one may deposit all the plates and high-k layers and then pattern all the plates, opening up contact holes to each of the plates. The contacts may be formed over the anchor structure, where there is a planar surface with all plates present. Similar to the previous description, the plates may have a top contact, a middle contact and a bottom contact such as shown in FIG. 1.

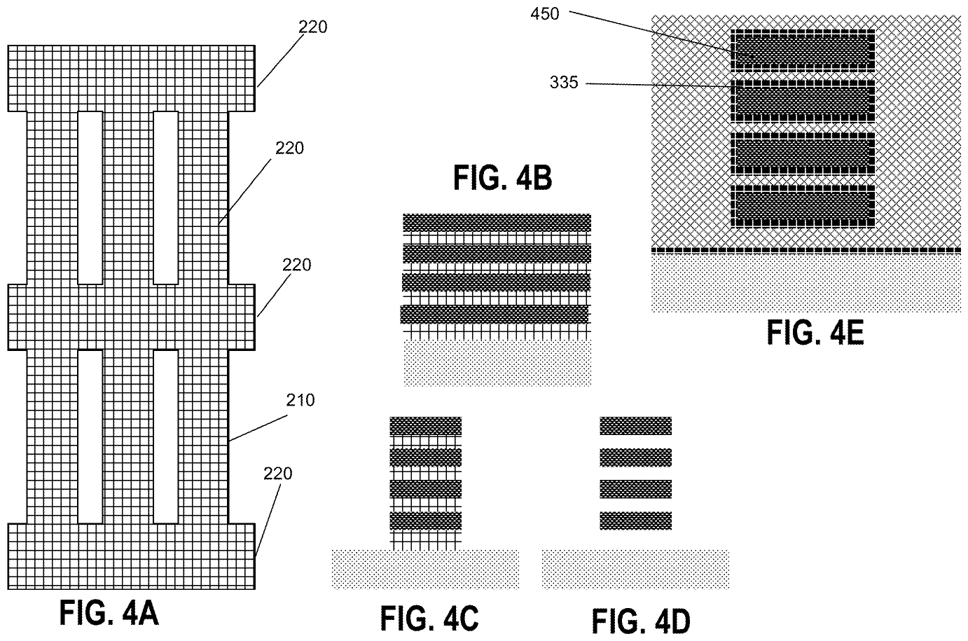

FIGS. 4A, 4B, 4C, 4D and 4E provide illustrations of a wrap-around metal-insulator-metal (MIM) capacitor with a conducting core plate according to an illustrative embodiment. Similar to FIG. 3A, FIG. 4A shows anchors 220 attached to contact regions 210. FIG. 4B shows in cross section layers of SiO₂ or another insulator, and conductive layers of Co, Rh, Ta, TaN, etc. Etching with hydrofluoric acid (HF) is performed on the section shown in FIG. 4C to remove SiO₂ (or another insulator if present). FIG. 4D shows the structure after the SiO₂ is etched away. FIG. 4E shows the plates arranged together with a conductor 450 having a high-K material 335.

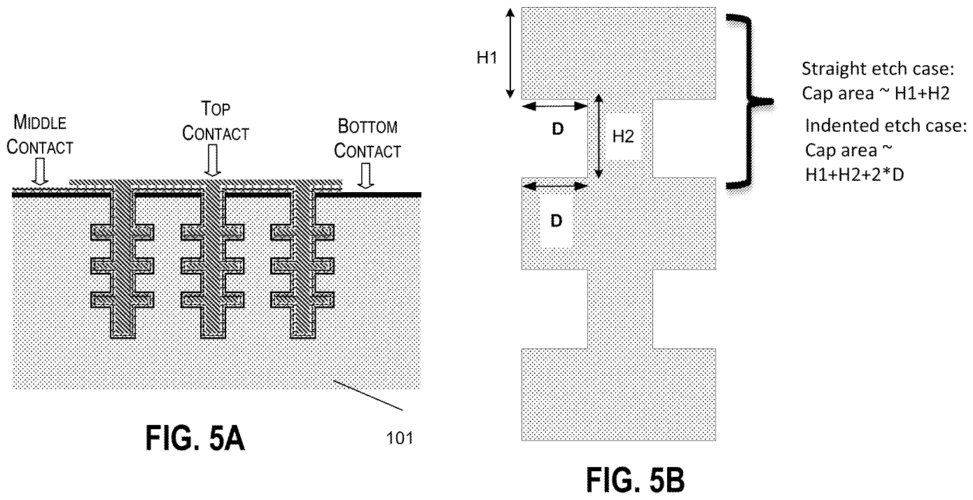

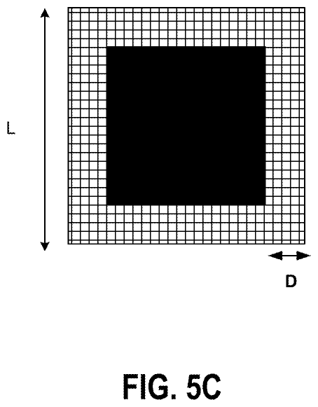

FIGS. 5A, 5B, illustrate capacitors with density differences based on etching according to an illustrative embodiment. FIG. 5A shows a silicon substrate 101 with a high-density capacitor configuration of FIG. 1. FIG. 5B shows a 2D example of a capacitor from a pillar structure such as shown in FIG. 5A. In a straight etch case, the capacitor area is H1+H2. This 2D example is relevant to a long rectangular capacitor structure, such as a rectangular prism. However, in an indented etch case the capacitor area is H1+H2+2*D, resulting in a 70% increase in area using indented cavities (a straight etch case having a C˜1.4 μm, and the indented etch case of C˜2.4 μm, if H1=1 μm, H2=400 nm). The effect becomes more dramatic for larger pillar widths.

FIG. 5C shows a top-down view of a 3D example of a capacitor structure having a density difference based on etching according capacitor structure, according to an illustrative embodiment. An improvement in capacitor density is achieved from the use of indented cavities. In this example, in an indented etch case, the length L=2 μm, D≤0.5 μm, H1=1 μm, and H2=400 nm. 4*H1*L+2*[L\hat{ }2−(L−2D)\hat{ }2]+4*H2*(L−2D) resulting in C˜15.6 for the 3D. In a straight etch case: C˜4*L*(H1+H2)=11.2. Thus, there is a 40% increase in 3D capacitor density with indented etches. The 2D structure assumes a uniform cross section for a dimension that such as a rectangular prism. The 3D structure explores the capacitance impact of the undercut feature on a pillar that has an undercut on all sides. This scenario is different for a long rectangular prism, where the ends of the shape do not contribute significantly to the overall capacitance of the structure and may be ignored.

### Example Process

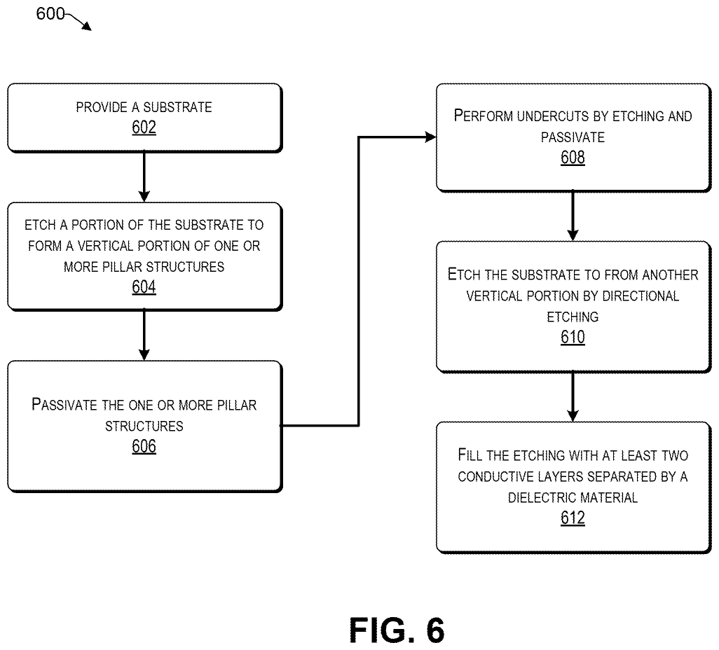

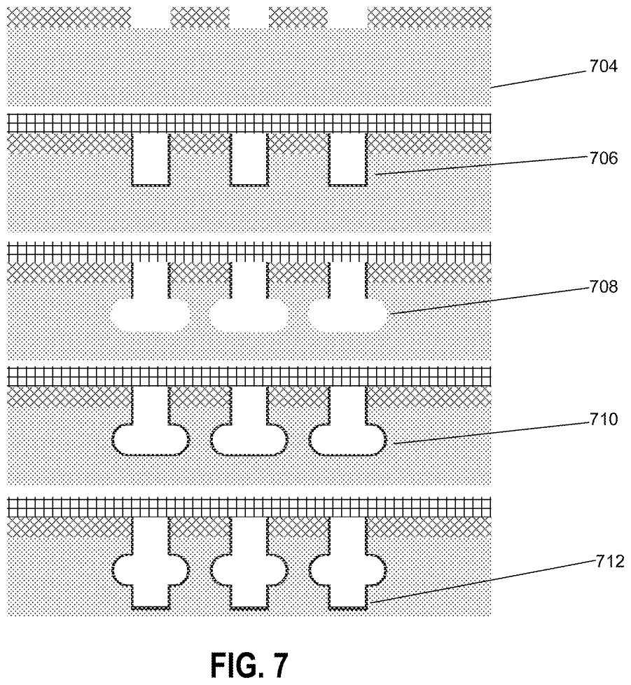

With the foregoing overview of the example architecture, it may be helpful now to consider a high-level discussion of an example process. To that end, FIG. 6 is a flowchart of a method of fabricating a high-density capacitor according to an illustrative embodiment. FIG. 7 is an illustration of the fabrication operations according to the acts discussed in the context of FIG. 6. FIG. 6 is shown as a collection of blocks, in a logical order, which represents a sequence of operations that can be implemented in a combination thereof.

A substrate, such as an Si substrate, is provided (602). There may be other materials combined with the Si, such as SiGe and others, as discussed previously. FIG. 7 shows a substrate 704 having a mask on an upper surface.

A portion of the substrate is etched to form a vertical portion of one or more pillar structures (604). FIG. 7 shows the directional etching of vertical pillars 706 (FIG. 7) in the substrate. In one embodiment, the etching to form the vertical portion of the pillars is directional etching. The sidewalls of the etched area are passivated with a protective film (606), and an isotropic etching occurs (608) to form indented cavities undercut into the substrate (see 708 in FIG. 7) that are substantially transverse to the direction etchings of the pillar. After passivation of the isotropically etched portion (see FIG. 710 in FIG. 7), another vertical portion is etched into the substrate (610) (see 712 in FIG. 7) and two conductive layers separated by a dielectric material is arranged in the pillars and undercuts.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, operations, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any such actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A capacitor structure, comprising:
a substrate;
a pillar structure within the substrate having vertical portions etched in the substrate;
one or more indented cavities and extending from between the vertical portions of the pillar structure substantially transverse to the vertical portions of the pillar structure; and
at least two conductive contact layers arranged within the vertical portions and the indented cavities of the pillar structure, the at least two conductive contact layers extending to a top surface of the substrate; and
a high-k dielectric material arranged between the at least two conductive contact layers configured to insulate the at least two conductive contact layers from each other.

2. The capacitor structure according to claim 1, wherein the vertical portions of the pillar structure are anisotropically etched, and wherein the one or more indented cavities are isotropically etched.

3. The capacitor structure according to claim 1, wherein:
the at least two conductive contact layers comprise three conductive contact layers;
the high-k dielectric material comprises two high-k dielectric layers alternately arranged with the three conductive contact layers within the vertical portions and the indented cavities of the pillar structure; and
the three conductive contact layers and the two high-k dielectric layers extend from the pillar structure to a top surface of the substrate.

4. The capacitor structure according to claim 3, wherein the substrate comprises a silicon substrate.

5. The capacitor structure according to claim 3, wherein the three conductive contact layers comprise metal layers forming capacitor plates alternately arranged with the high-k dielectric layers.

6. The capacitor structure according to claim 5, wherein the metal layer is selected from Co, Rh, Ta, TaN, and AlCu.

7. The capacitor structure according to claim 5, wherein the metal layers comprise a top contact, a middle contact, and a bottom contact alternately arranged with the high-k dielectric layers.

8. The capacitor structure according to claim 7, wherein the bottom contact comprises a doped Si material.

9. The capacitor structure according to claim 1, wherein the indented cavities comprise a plurality of partial undercuts in the substrate substantially transverse to the vertical portions of the pillar structure.

10. The capacitor structure according to claim 1, wherein the indented cavities comprise a plurality of full undercuts in the substrate substantially transverse to a direction of the pillar structure, and at least one anchor attached to the full undercuts.

11. The capacitor structure according to claim 1, wherein the indented cavities comprise:
at least one partial undercut in the substrate substantially transverse to the vertical portions of the pillar structure;
at least one full undercut in the substrate substantially transverse to a direction of the pillar structure; and
at least one anchor attached to the full undercut.

12. The capacitor structure according to claim 1, wherein the indented cavities are arranged in a sidewall of the pillar structure.

13. The capacitor structure according to claim 1, wherein the pillar structure comprises a plurality of pillars laterally arranged in the substrate.

14. The capacitor structure according to claim 1, wherein the pillar structure is arranged in a trench within the substrate.

15. A capacitor structure, comprising:
a substrate;
a pillar structure etched into a film on the substrate;
one or more indented cavities extending from the pillar structure; and
a plurality of conductive layers and high-k dielectric layers alternately arranged within the pillar structure including the indented cavities,
wherein the plurality of conductive contact layers and the high-k dielectric layers extend from the pillar structure to a top surface of the substrate.

16. The capacitor structure according to claim 15, wherein the capacitor structure comprises a discrete capacitor.

17. The capacitor structure according to claim 15, wherein the capacitor structure comprises an integrated capacitor.

18. A metal-insulator-metal (MIM) capacitor, comprising:
a substrate having alternating layers fully undercut, the fully undercut layers comprising a plurality of plates;
an anchor attached to the substrate and to the plurality of plates;
a plurality of plates attached to the anchor; wherein each plate includes a core, and at least two metal layers separated by a high-k insulator on the core; and
at least two contacts, each contact is connected to one of the two metal layers, respectively.

19. The MIM capacitor according to claim 18, wherein each plate includes an insulating core, a first metal layer deposited on the insulating core, a high-k layer on the first metal layer, and a second metal layer deposited on the high-k layer; and
each contact is connected to one of the first metal layer or the second metal layer,
wherein the plurality of plates is vertically arranged, and a bottom plate is in contact with the substrate.

20. The MIM capacitor structure according to claim 18, wherein one of the two metal layers of each plate includes a conductive core, a high-k layer on the conductive core, and a second metal layer deposited on the high-k layer; and
each contact is connected to one of the first metal layer or the second metal layer.
